(19) United States
(12) Patent Application Publication
(10) Pub. No.: US 2017/0336040 A1
(43) Pub. Date: Nov. 23, 2017

(54) LED LIGHT SOURCE FOR VEHICLE-MOUNTED HEADLIGHT

(71) Applicant: SHIN-ETSU CHEMICAL CO., LTD., Tokyo (JP)

(72) Inventors: Toshihiro TSUMORI, Echizen-shi (JP); Toshihiko TSUKATANI, Echizen-shi (JP); Kazuhiro WATAYA, Echizen-shi (JP); Takehisa MINOWA, Echizen-shi (JP)

(73) Assignee: SHIN-ETSU CHEMICAL CO., LTD., Tokyo (JP)

(21) Appl. No.: 15/534,125

(22) PCT Filed: Dec. 2, 2015
(86) PCT No.: PCT/JP2015/083839

§ 371 Date: Jun. 8, 2017

(30) Foreign Application Priority Data
Dec. 9, 2014 (JP) 2014-248699

(51) Int. Cl. F21S 8/10; H01L 33/50; F21Y 2115/10

(52) U.S. Cl. CPC F21S 48/115; F21S 48/13; H01L 33/504; F21Y 2115/10; H01L 33/501

(57) ABSTRACT

This LED light source for a vehicle-mounted headlight is provided with: a blue LED that emits blue light having a dominant wavelength of 430-470 nm; and a fluorescent material that is arranged forward in the light emission direction of the blue light and that performs wavelength conversion of the blue light. The main fluorescent material constituting the fluorescent material is a celium-activated lutetium/aluminum/garnet fluorescent material represented by Lu₃Al₅O₁₂:Ce. The LED light source for a vehicle-mounted headlight emits pseudo-white light that has a color temperature of 6,000 K or less and that is unlikely to decrease in visibility even during bad weather. The LED light source for a vehicle-mounted headlight has characteristics such as a wide lighting range and excellent visibility in the peripheral area of the visual field (the peripheral visual field) and can thus contribute to accident prevention and road traffic safety.

### TECHNICAL FIELD

This invention relates to a LED light source for vehicle-mounted headlamps.

### BACKGROUND ART

In association with the recent widespread use of LED illumination, a change to LED lamps takes place in the automotive field. For the vehicle-mounted headlamp application, LED light sources have advantages including high impact resistance, extremely higher emission efficiency than conventional incandescent lamps such as halogen lamps, and high freedom of emission spectrum.

Widely used as the white LED light source for general illumination is a pseudo-white LED lamp comprising blue LED as a light source, and a phosphor Y₃Al₅O₁₂:Ce disposed forward in the emission direction of the blue LED for converting part of blue light to yellow light, wherein yellow light is combined with unconverted blue light from the blue LED to produce white light.

The phosphor Y₃Al₅O₁₂:Ce has a broad emission spectrum having a peak near 555 nm which is a peak of human photopic sensitivity. On use of the pseudo-white LED lamp, satisfactory color development and high luminance are available.

However, when vehicle-mounted headlamps and other light sources for use in outdoor dark places at night are considered, the emission peak near wavelength 555 nm is rarely regarded adequate. This is because in the case of human eyes, the luminosity factor at 500 nm which is shorter than the wavelength 555 nm and nearby is significantly increased in an environment with a low illuminance of less than 1 lx, typically at night. As the ambient illuminance lowers, the luminosity factor wavelength shifts from the photopic wavelength region peaking at wavelength 555 nm to the scotopic wavelength region peaking at wavelength 507 nm as shown in FIG. 6. This shift of luminosity factor wavelength region is well known as the Purkinje effect. It is accordingly known that an improvement in luminosity factor in the dark is especially outstanding in the peripheral vision region of human eyes. In the field of LED lamps, a high color temperature lamp capable of producing emission with rich blue component for the purpose of increasing the luminous efficiency in the dark so as to comply with a shift of luminosity factor wavelength known as the Purkinje effect, is proposed as the LED lamp for use in the dark. Also in the field of the LED light source for vehicle-mounted headlamps to be used in the dark, an improvement in visibility, especially visibility in a peripheral portion of the visual field is expectable from the use of a high color temperature light source.

In addition to the performance as general outdoor illumination, the vehicle-mounted headlamp is required to ensure good visibility in bad weather such as rain and fog. However, the high color temperature light, especially LED light with rich blue component, undergoes more scattering due to water droplets, and on use in bad weather, an inevitable drop of visibility. Therefore, the guideline for vehicle-mounted lamps recommends that many vehicle-mounted lamps have a color temperature of up to 6,000 K. Although the LED lamp has adequate properties for headlamps on vehicles using batteries as the power supply including higher emission efficiency and higher illuminance than conventional lamps, its emission contains more blue component and has a relatively high color temperature. On the other hand, the vehicle-mounted headlamp using a conventional incandescent lamp contains a certain proportion of light component in the scotopic luminosity factor region even at a color temperature of up to 6,000 K, but its emission efficiency is significantly low as compared with LED lamps, resulting in some shortage of illuminance.

### PRIOR ART DOCUMENTS

### Patent Documents

Patent Document 1: JP-A 2013-065555

Patent Document 2: JP-A 2009-272092

Patent Document 3: JP-A 2012-204071

Patent Document 4: JP-A 2012-221633

Patent Document 5: JP-A 2012-221634

### SUMMARY OF THE INVENTION

### Problems to be Solved by the Invention

An object of the invention, which has been made under the above-mentioned circumstances, is to provide a high efficiency LED light source for a vehicle-mounted headlamp, which produces an emission spectrum having a color temperature of up to 6,000 K adequate in bad weather such as rain and fog, and a satisfactory visibility at night, especially in a peripheral area of illuminating light that affects the visibility of peripheral vision field of human eyes at night.

### Means for Solving the Problems

Focusing on the Purkinje effect in order to solve the outstanding problems, the inventors made a study on a LED light source containing more a green light component at wavelength 500 nm or nearby as the LED light source for vehicle-mounted headlamps, adapted to produce light with a color temperature of up to 6,000 K and good visibility even at a low illuminance.

As a result of extensive investigations, the inventors have found that by using a phosphor Lu₃Al₅O₁₂:Ce having a peak of green fluorescence near wavelength 500 nm, as the main phosphor governing the color of fluorescent emission, that is, the main wavelength of fluorescent emission, in combination with a blue LED which emits blue light having a dominant wavelength of from 430 nm to 470 nm, the luminosity factor properties in the dark can be improved without elevating the color temperature; and that by using an auxiliary phosphor such as phosphor K₂SiF₆:Mn or Y₃Al₅O₁₂:Ce along with the phosphor Lu₃Al₅O₁₂:Ce, a LED light source for scotopic vision having natural emission color as well as visibility is obtained.

Making extensive investigations on the emission spectrum of a LED light source for scotopic vision in order to use it in the vehicle-mounted headlamp, the inventors have found that the LED light source having such an emission spectrum that the total of emission energy in a wavelength range from 470 nm to 540 nm (falling in the peak wavelength region among the scotopic vision wavelength region) is at least 0.7 time the total of emission energy in a wavelength range from 510 nm to 610 nm (falling in the peak wavelength region among the photopic vision wavelength region), or the LED light source having such an emission spectrum that the total of emission energy in a wavelength range from 470 nm to 540 nm (falling in the peak wavelength region among the scotopic vision wavelength region) is at least 0.4 time the total of emission energy in a wavelength range from 430 nm to 630 nm (corresponding to the majority of the photopic vision wavelength region), especially the LED light source meeting both the ratios is an appropriate LED light source for a vehicle-mounted headlamp, having a high emission efficiency, and the advantages of incandescent lamps including visibility and a minimal reduction of visual perception response time in a low-illuminance environment at night, even at a color temperature of up to 6,000 K, like incandescent bulb headlamps. The present invention is predicated on these findings.

Accordingly, the invention provides a LED light source for a vehicle-mounted headlamp as defined below.
[1] A LED light source for a vehicle-mounted headlamp, comprising a blue LED which emits blue light having a dominant wavelength of from 430 nm to 470 nm, and a phosphor disposed forward in the emission direction of blue light and capable of wavelength conversion of blue light, said phosphor comprising a cerium-activated lutetium-aluminum garnet phosphor represented by Lu₃Al₅O₁₂:Ce as a main phosphor, the LED light source emitting pseudo-white light having a color temperature of up to 6,000 K.
[2] The LED light source for a vehicle-mounted headlamp of [1] wherein said phosphor capable of wavelength conversion of blue light further comprises a manganese-activated potassium fluorosilicate phosphor represented by K₂SiF₆:Mn or a cerium-activated yttrium-aluminum garnet phosphor represented by Y₃Al₅O₁₂:Ce as an auxiliary phosphor.
[3] The LED light source for a vehicle-mounted headlamp of [1] or [2] which emits pseudo-white light having such an emission spectrum that the total of emission energy in a wavelength range from 470 nm to 540 nm is at least 0.7 time the total of emission energy in a wavelength range from 510 nm to 610 nm.
[4] The LED light source for a vehicle-mounted headlamp of any one of [1] to [3] which emits pseudo-white light having such an emission spectrum that the total of emission energy in a wavelength range from 470 nm to 540 nm is at least 0.4 time the total of emission energy in a wavelength range from 430 nm to 630 nm.
[5] The LED light source for a vehicle-mounted headlamp of any one of [1] to [4] wherein said phosphor capable of wavelength conversion of blue light is disposed as a phosphor layer having the phosphor dispersed in a polymeric material or inorganic glass.

### Advantageous Effects of the Invention

The LED light source for a vehicle-mounted headlamp has advantages including emission of light having a color temperature of up to 6,000 K, which is believed to have a rare chance of visibility lowering even in bad weather, a wide range of lighting, and improved visibility in a peripheral area of the visual field (peripheral visual field). It thus contributes to accident prevention and traffic safety.

### BRIEF DESCRIPTION OF THE DIAGRAMS

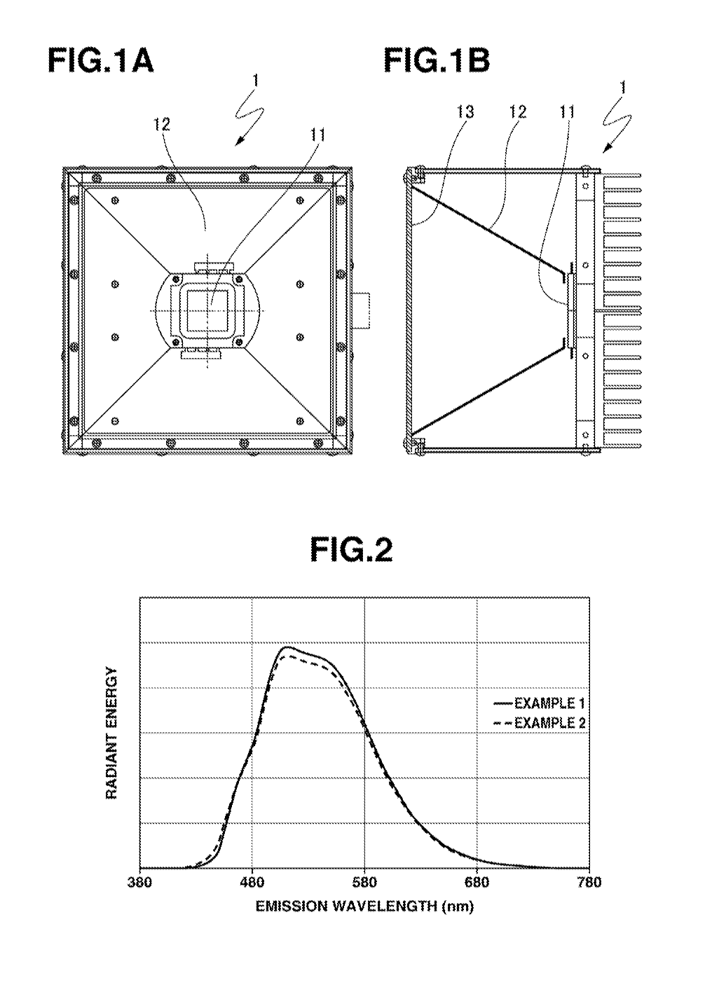

FIG. 1 illustrates a lighting fixture fabricated in Examples and Comparative Examples, FIG. 1A being a plan view and FIG. 1B being a cross-sectional view.

FIG. 2 is a diagram showing emission spectra of lighting fixtures in Examples 1 and 2.

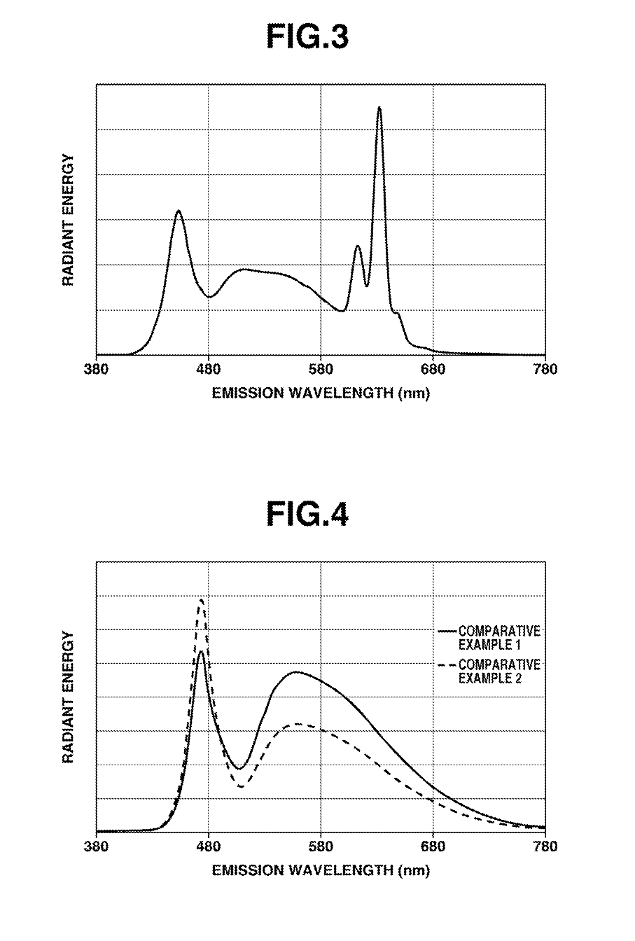

FIG. 3 is a diagram showing emission spectrum of a lighting fixture in Example 3.

FIG. 4 is a diagram showing emission spectra of lighting fixtures in Comparative Examples 1 and 2.

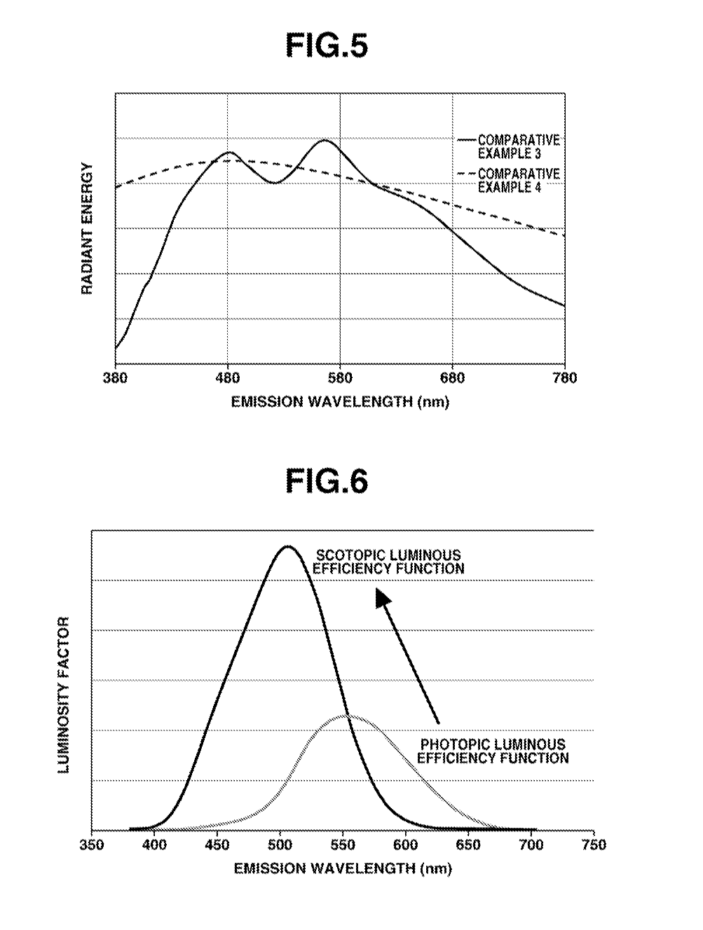

FIG. 5 is a diagram showing emission spectra of lighting fixtures in Comparative Examples 3 and 4.

FIG. 6 is a diagram showing the peak wavelength in photopic vision and the peak wavelength in scotopic vision of the visual sensitivity of human eye.

### EMBODIMENT FOR CARRYING OUT THE INVENTION

Below the LED light source for a vehicle-mounted headlamp according to the invention is described in detail.

The invention provides a LED light source for a vehicle-mounted headlamp, comprising a blue LED which emits blue light and a phosphor capable of wavelength conversion of blue light, wherein a cerium-activated lutetium-aluminum garnet phosphor represented by Lu₃Al₅O₁₂:Ce (referred to as LuAG:Ce phosphor) is used as the phosphor capable of wavelength conversion of blue light. In response to excitation light (blue light), the phosphor Lu₃Al₅O₁₂:Ce emits green luminescence having a peak near wavelength 500 nm which is the dominant wavelength in the scotopic luminosity factor region. The preferred phosphor Lu₃Al₅O₁₂:Ce has a Ce content from 0.2% to 10% by weight.

While emission of green light having a close peak wavelength is obtainable from LEDs of green monochromatic emission such as InGaN, the emission spectrum, which is a bright-line spectrum with substantially no wavelength distribution, contains little of light other than green light at wavelength 500 nm and nearby. Since a luminosity factor at an illuminance of at least 1 lx is necessary for the light source for a vehicle-mounted headlamp, LED capable of emitting green monochromatic light not containing a color component other than green is not suited in this application. In contrast, since the emission spectrum of the phosphor Lu₃Al₅O₁₂:Ce upon excitation with blue light is broad, it is possible to produce pseudo-white light having an average color rendering index of at least 50 as photopic vision illumination as well as visibility in scotopic vision.

In the LED light source for a vehicle-mounted headlamp, the phosphor Lu₃Al₅O₁₂:Ce is disposed forward in the emission direction of blue light from the blue LED. The blue LED used herein is one that emits blue light having a dominant wavelength of from 430 nm to 470 nm, and may be selected from prior art well-known LEDs including commercially available ones.

The phosphor may be disposed in various embodiments, for example, an embodiment wherein the phosphor as such or a phosphor layer, which is formed by dispersing the phosphor in a polymeric material such as resin or a solvent, and potting or coating the material, is disposed forward of the blue LED, for example, forward in the emission direction of a light-emitting chip (light-emitting semiconductor) or forward of the encapsulant enclosing light-emitting semiconductor in the light emission direction of the blue LED; an embodiment wherein a phosphor layer, which is formed by mixing and dispersing the phosphor in a polymeric material such as a thermosetting resin or thermoplastic resin or inorganic glass, is disposed closely forward of the encapsulant enclosing light-emitting chip in the light emission direction of the blue LED; and an embodiment wherein the phosphor layer is disposed forward of and spaced apart from the encapsulant (known as “remote phosphor type”).

The phosphor Lu₃Al₅O₁₂:Ce is particulate and its particle size is preferably from 1 μm to 150 μm, more preferably from 5 μm to 50 μm, and even more preferably from 10 μm to 25 μm, expressed as an average particle diameter D50. If the particle size is less than 1 μm, the conversion efficiency (quantum efficiency) from blue light to luminescent light may lower, leading to shortage of a fluorescent light quantity and a lowering of emission efficiency. If the particle size exceeds 150 μm, it may be difficult to form a uniform dense phosphor layer, and a structural problem may arise that wider gaps are defined between particles, allowing a more than necessity amount of blue light to pass through the gaps.

Since the light emission from the phosphor Lu₃Al₅O₁₂:Ce is centered at wavelength 500 nm and nearby, it is suited as lighting in the dark or at a low illuminance, but its illuminance at a place where sufficient brightness is available, for example, on the optical axis near the light source is somewhat low, as compared with conventional incandescent lamps and prior art pseudo-white LED lamps mainly using phosphor Y₃Al₅O₁₂:Ce. In addition, since a red component near 600 nm is short, the color reproduction, especially red reproduction is relatively low.

These problems may be overcome by using the phosphor Lu₃Al₅O₁₂:Ce as a main phosphor that predominantly governs the color of fluorescent light, i.e., the main wavelength of fluorescent light, and adding thereto a manganese-activated potassium fluorosilicate phosphor represented by K₂SiF₆:Mn or a cerium-activated yttrium-aluminum garnet phosphor (YAG:Ce phosphor) represented by Y₃Al₅O₁₂:Ce as an auxiliary phosphor, so that the light quantity of wavelength 500 to 630 nm is increased for thereby improving the quality of white light, specifically color deviation (Δuv). Although examples of the phosphor capable of producing light of red wavelength include red phosphors such as CASN, S-CASN, and α-SiALON, these phosphors are inadequate in the practice of the invention. This is because these phosphors absorb a green light component from the phosphor Lu₃Al₅O₁₂:Ce, resulting in a substantial drop of emission efficiency.

In the embodiment wherein the phosphor K₂SiF₆:Mn is added as an auxiliary phosphor, red light at 630 nm and nearby is added to the light emission from the phosphor Lu₃Al₅O₁₂:Ce at 500 nm and nearby, whereby the light quality of a lighting fixture is significantly improved. This is followed by only a slight lowering of light quantity because the re-absorption of the light emission from the phosphor Lu₃Al₅O₁₂:Ce by the phosphor K₂SiF₆:Mn is substantially nil, and the emission spectrum is substantially free of any component which does not contribute to pseudo-white formation. The phosphor K₂SiF₆:Mn preferably has a Mn content from 0.05% to 7% by weight. The phosphor K₂SiF₆:Mn used herein is particulate and its particle size is preferably from 2 μm to 200 μm, more preferably from 10 μm to 60 μm, expressed as an average particle diameter D50.

In the embodiment wherein the phosphor Y₃Al₅O₁₂:Ce is added as an auxiliary phosphor, its emission spectrum is such that the light quantity is increased in a wavelength region on a long wavelength side of the light emission from the phosphor Lu₃Al₅O₁₂:Ce, whereby the color temperature is lowered and red reproduction is improved. The phosphor Y₃Al₅O₁₂:Ce preferably has a Ce content from 1% to 6% by weight. The phosphor Y₃Al₅O₁₂:Ce used herein is particulate and its particle size is preferably from 1 μm to 100 μm, more preferably from 5 μm to 50 μm, expressed as an average particle diameter D50.

The phosphor Lu₃Al₅O₁₂:Ce as the main phosphor and the auxiliary phosphor other than Lu₃Al₅O₁₂:Ce (phosphor K₂SiF₆:Mn, phosphor Y₃Al₅O₁₂:Ce or the like) are preferably mixed such that the main phosphor accounts for at least 10% by weight, more preferably at least 20% by weight and up to 50% by weight, more preferably up to 40% by weight based on the total weight of phosphors.

The phosphors used herein may be prepared by any prior art well-known methods or commercially available ones may be used.

While the thickness of the phosphor layer is set appropriate to provide the desired emission spectrum which is effective as the LED light source for vehicle-mount headlamp, the thickness is preferably 0.1 to 10 mm, more preferably 0.5 to 3 mm.

Also, in the phosphor layer having the phosphor dispersed in a polymeric material or inorganic glass, the content of phosphors in the phosphor layer is preferably at least 5% by weight, more preferably at least 10% by weight, even more preferably at least 20% by weight and up to 60% by weight, more preferably up to 40% by weight, even more preferably up to 25% by weight as the total weight of phosphors. For example, when a phosphor layer of 0.3 mm thick is formed by potting phosphor-dispersed polymeric material, the phosphor content is preferably from 20% to 60% by weight. When a molded body of 2 mm thick is formed by milling the phosphor and polymeric material and molding the material and used as a remote phosphor member, the phosphor content is preferably from 5% to 25% by weight. If the phosphor content is lower, more transmission of unconverted blue light from the blue LED may occur, leading to a higher color temperature. Inversely, if the phosphor content is higher, the attenuation amount of light may be increased, leading to a reduction of light quantity.

In the phosphor layer, a light scattering agent such as SiO₂, SiON or TiO may be added as an additive for the purpose of preventing blue light from passing through without entering the phosphor, i.e., preventing the so-called blue pass, for example, in an amount of from 0.1% to 5% by weight.

The LED light source comprising the blue LED capable of emitting blue light having a dominant wavelength from 430 nm to 470 nm and the phosphor Lu₃Al₅O₁₂:Ce as a main phosphor, especially the phosphor Lu₃Al₅O₁₂:Ce in combination with the phosphor K₂SiF₆:Mn or phosphor Y₃Al₅O₁₂:Ce as an auxiliary phosphor, may emit pseudo-white light having a color temperature of up to 6,000 K while suppressing a reduction of scotopic vision efficiency.

The LED light source may emit pseudo-white light having such an emission spectrum that the total of emission energy in a wavelength range from 470 nm to 540 nm mainly corresponding to the emission wavelength of green region is at least 0.7 time, specifically from 0.8 time to 1.5 times, the total of emission energy in a wavelength range from 510 nm to 610 nm. If this energy ratio is less than 0.7, the effect of improving scotopic visibility may not be exerted. Also, the LED light source may emit pseudo-white light having such an emission spectrum that the total of emission energy in a wavelength range from 470 nm to 540 nm corresponding to the emission wavelength of green region is at least 0.4 time, specifically from 0.5 time to 0.7 time, the total of emission energy in a wavelength range from 430 nm to 630 nm corresponding to the majority of photopic luminosity factor region. When this energy ratio is equal to or more than 0.4, a higher effect of improving scotopic visibility may be exerted. It is thus most advantageous for the LED light source to meet both the ratios. Notably, the total of emission energy in the wavelength range defined above is an accumulative value (integrated value) of radiation energy (intensity) in each wavelength range in the emission spectrum.

The invention provides a LED light source which emits pseudo-white light having a color temperature of up to 6,000 K which is believed to undergo little drop of visibility even in bad weather, wherein the lowering of visibility by a shift of luminosity factor wavelength due to the Purkinje effect in a low illuminance environment, typically at night, is improved. The LED light source is thus best suited for a vehicle-mounted headlamp.

### EXAMPLES

Examples and Comparative Examples are given below for illustrating the invention, but the invention is not limited thereto.

### Example 1

The blue light source used was royal blue LED array (ShenZhen HanHua Opto Co., Ltd., emission wavelength 445 nm, 50 W). The LED array was coated on its emissive surface with a slurry (phosphor concentration 26 wt %) which was prepared by dispersing Lu₃Al₅O₁₂:Ce phosphor particles with a Ce content of 1.4 wt % (particle size D50=16.2 μm) in an epoxy resin composition Specifix (Marumoto Struers K.K.). The coating was cured by heating in an oven at 50° C. for 3.5 hours. There was obtained a pseudo-white LED chip having a phosphor layer of ˜0.4 mm thick laid on the emissive surface of LED. Next, as shown in FIG. 1, a test lighting fixture (LED light source) 1 was assembled by placing the pseudo-white LED chip 11 at the center of a reflector 12 and using a milky white acrylic resin plate of 2 mm thick as a shade 13. The orientation angle of illumination was 115° as ½ luminous intensity distribution angle.

Of optical properties of this lighting fixture, a color temperature was evaluated by illuminance spectrophotometer CL-500A (Konica Minolta Inc.) and an emission efficiency was evaluated by total luminous flux measurement system FM-1650 (Otsuka Electronic Co., Ltd.). An emission spectrum is shown in FIG. 2. From this emission spectrum, the total amount of emissive energy in a wavelength range from 470 nm to 540 nm and the total amount of emissive energy in a wavelength range from 510 nm to 610 nm were measured, and a ratio of them (ratio A) was computed. Also, the total amount of emissive energy in a wavelength range from 470 nm to 540 nm and the total amount of emissive energy in a wavelength range from 430 nm to 630 nm were measured, and a ratio of them (ratio B) was computed. The results are shown in Table 1 together with the color temperature of emission, color deviation (Δuv), emission efficiency and S/P ratio.

Further, the visibility in scotopic vision of the lighting fixture was evaluated by the following method as a difference in perception response time of peripheral visual field at a low lighting illuminance. First, the lighting fixture was installed at the center of a 7-m wide asphalt road at a height of 50 cm at night, with its optical axis kept horizontal. Next, a chroma of 15 cm squares with a Munsell value of 7.5 was placed at any one of three positions, a position (front) disposed on the optical axis and spaced 12 m forward of the emissive surface of the lighting fixture and positions disposed on the left and right shoulder sides from the front position and spaced ˜10.6 m apart from the emissive surface of the lighting fixture. The illuminance of the lighting fixture was adjusted such that the chroma at the front position was illuminated at an illuminance of 10 lx. In this condition, a sensory test was carried out by letting an examinee stand at a position disposed 1 m backward of the lighting fixture and direct his line of sight in the optical axis direction, burning the test LED light source, and measuring a time passed from the start of illumination until the chroma at any position was perceived. The panel consisted of three examinees, the chroma was randomly installed at any of three positions, and tests were performed at intervals of 5 minutes and 5 times at each position, totaling to 15 tests. The average response time at each position is reported in Table 1.

### Example 2

The blue light source in Example 1 was used as such without coating the phosphor layer thereon. The Lu₃Al₅O₁₂:Ce phosphor particles in Example 1 were milled in a transparent acrylic resin Delpet 60N (Asahi Kasei Corp.), which was molded into a plate of 2 mm thick (phosphor concentration 9 wt %). Using the plate as a phosphor layer and shade, a test LED light source of remote phosphor type was fabricated. As in Example 1, optical properties and visibility were evaluated. The emission spectrum is shown in FIG. 2 and the other results are reported in Table 1.

### Example 3

A test LED light source of remote phosphor type was fabricated as in Example 2 except that the Lu₃Al₅O₁₂:Ce phosphor particles in Example 1 was combined with K₂SiF₆:Mn phosphor particles having a Mn content of 2 wt % (particle size D50=20 μm), and a plate of 2 mm thick (Lu₃Al₅O₁₂:Ce phosphor concentration 10 wt %, K₂SiF₆:Mn phosphor concentration 5 wt %) was used as a phosphor layer and shade. As in Example 1, optical properties and visibility were evaluated. The emission spectrum is shown in FIG. 3 and the other results are reported in Table 1.

### Comparative Example 1

A test LED light source was fabricated as in Example 1 except that the blue light source in Example 1 was coated on its emissive surface with a slurry (phosphor concentration 32 wt %) which was prepared by dispersing Y₃Al₅O₁₂:Ce phosphor particles with a Ce content of 1.6 wt % (particle size D50=14 μm) in the epoxy resin composition in Example 1. As in Example 1, optical properties and visibility were evaluated. The emission spectrum is shown in FIG. 4 and the other results are reported in Table 1.

### Comparative Example 2

A test LED light source was fabricated as in Example 1 except that the blue light source in Example 1 was coated on its emissive surface with a slurry (phosphor concentration 32 wt %) which was prepared by dispersing Y₃Al₅O₁₂:Ce phosphor particles with a Ce content of 1.6 wt % (particle size D50=14 μm) in the epoxy resin composition in Example 1, and the coating weight was changed to 21% of Comparative Example 1. As in Example 1, optical properties and visibility were evaluated. The emission spectrum is shown in FIG. 4 and the other results are reported in Table 1.

### Comparative Example 3

A test lighting fixture was fabricated as in Example 1 except that instead of the pseudo-white LED chip 11 in the test lighting fixture 1 shown in FIG. 1, a commercial day-white halogen bulb was installed at the center of the reflector 12 and backward thereof, with the bulb penetrating through the substrate, such that the distal end of its lighting spherical surface (emissive surface) was situated at the same position as the distal end of the pseudo-white LED chip 11 in Example 1, and a glass plate of 1.5 mm thick was used as the shade 13. As in Example 1, optical properties and visibility were evaluated. The emission spectrum is shown in FIG. 5 and the other results are reported in Table 1.

### Comparative Example 4

A test lighting fixture was fabricated as in Comparative Example 3 except that a commercial white incandescent bulb was used instead of the halogen bulb in the test lighting fixture 1 shown in FIG. 1. As in Example 1, optical properties and visibility were evaluated. The emission spectrum is shown in FIG. 5 and the other results are reported in Table 1.

TABLE 1

| | | | | | | | Average response | | |
|---|---|---|---|---|---|---|---|---|---|
| | Color | Color | Emission | | Total emission | | time (sec.) | | |
| | temperature | deviation | efficiency | S/P | energy ratio | | Left | | Right |
| | (K) | (Δuv) | (lm/W) | ratio | Ratio A | Ratio B | shoulder | Front | shoulder |
| Example 1 | 5,900 | 0.073 | 82 | 2.24 | 0.764 | 0.505 | 0.53 | 0.48 | 0.52 |
| Example 2 | 6,000 | 0.072 | 93 | 2.25 | 0.765 | 0.501 | 0.53 | 0.52 | 0.54 |
| Example 3 | 5,400 | −0.005 | 81 | 2.21 | 0.800 | 0.413 | 0.52 | 0.49 | 0.51 |
| Comparative | 5,600 | 0.003 | 95 | 2.02 | 0.554 | 0.334 | 0.64 | 0.62 | 0.66 |
| Example 1 | | | | | | | | | |
| Comparative | 7,600 | 0.009 | 86 | 2.35 | 0.747 | 0.298 | 0.48 | 0.49 | 0.49 |
| Example 2 | | | | | | | | | |
| Comparative | 5,400 | 0.005 | 16 | 2.21 | 0.686 | 0.357 | 0.52 | 0.51 | 0.53 |
| Example 3 | | | | | | | | | |
| Comparative | 6,000 | 0.000 | 18 | 2.36 | 0.736 | 0.366 | 0.46 | 0.48 | 0.47 |
| Example 4 | | | | | | | | | |

S/P ratio

$$[ Mathematical Formula 1 ]$$

$$\sum [ \frac{\begin{matrix}( emission at each wavelength ) \times \\ ( scotopic luminous efficiency function )\end{matrix}}{\begin{matrix}( emission at each wavelength ) \times \\ ( photopic luminous efficiency function )\end{matrix}} ]$$

Total emission energy ratio (Ratio A)
   (total amount of emissive energy in an emission spectrum wavelength range from 470 nm to 540 nm)/(total amount of emissive energy in an emission spectrum wavelength range from 510 nm to 610 nm)
Total emission energy ratio (Ratio B)
   (total amount of emissive energy in an emission spectrum wavelength range from 470 nm to 540 nm)/(total amount of emissive energy in an emission spectrum wavelength range from 430 nm to 630 nm)

The average response time at the left and right shoulders under LED lighting of Examples 1 to 3 is reduced about 20% as compared with the conventional pseudo-white LED using phosphor Y₃Al₅O₁₂:Ce in Comparative Example 1, indicating that the LED light source of the invention has satisfactory visibility at the peripheral portion of illuminating light that affects the visibility of peripheral visual field at night. Although the average response time at the left and right shoulders under LED using phosphor Y₃Al₅O₁₂:Ce having a higher color temperature of emission in Comparative Example 2 is shorter than in Examples 1 to 3, that color temperature is higher than 6,000 K, the upper limit of the guideline for vehicle-mount lighting. This is inadequate as the vehicle-mount headlamp for which the utilization under bad weather such as rain and fog must be taken into account. On the other hand, the conventional halogen bulb in Comparative Example 3 and the incandescent bulb in Comparative Example 4 show that although their scotopic response time is good, their emission efficiency is as low as about ⅕ of that of the inventive LED light source.

### REFERENCE SIGNS LIST

1 lighting fixture (LED light source)

11 pseudo-white LED chip

12 reflector

13 shade or phosphor layer

1. A LED light source for a vehicle-mounted headlamp, comprising a blue LED which emits blue light having a dominant wavelength of from 430 nm to 470 nm, and a phosphor disposed forward in the emission direction of blue light and capable of wavelength conversion of blue light, said phosphor comprising a cerium-activated lutetium-aluminum garnet phosphor represented by Lu₃Al₅O₁₂:Ce as a main phosphor, the LED light source emitting pseudo-white light having a color temperature of up to 6,000 K.

2. The LED light source for a vehicle-mounted headlamp of claim 1 wherein said phosphor capable of wavelength conversion of blue light further comprises a manganese-activated potassium fluorosilicate phosphor represented by K₂SiF₆:Mn or a cerium-activated yttrium-aluminum garnet phosphor represented by Y₃Al₅O₁₂:Ce as an auxiliary phosphor.

3. The LED light source for a vehicle-mounted headlamp of claim 1 which emits pseudo-white light having such an emission spectrum that the total of emission energy in a wavelength range from 470 nm to 540 nm is at least 0.7 time the total of emission energy in a wavelength range from 510 nm to 610 nm.

4. The LED light source for a vehicle-mounted headlamp of claim 1 which emits pseudo-white light having such an emission spectrum that the total of emission energy in a wavelength range from 470 nm to 540 nm is at least 0.4 time the total of emission energy in a wavelength range from 430 nm to 630 nm.

5. The LED light source for a vehicle-mounted headlamp of claim 1 wherein said phosphor capable of wavelength conversion of blue light is disposed as a phosphor layer having the phosphor dispersed in a polymeric material or inorganic glass.
